(19) United States
(12) Patent Application Publication
(10) Pub. No.: US 2019/0021163 A1
(43) Pub. Date: Jan. 17, 2019

(54) Z-AXIS GUARDBANDING USING VERTICAL GROUND CONDUCTORS FOR CROSSTALK MITIGATION

(71) Applicants: Robert C. Shelsky, Nashua, NH (US); Kenneth W. Graham, Nashua, NH (US)

(72) Inventors: Robert C. Shelsky, Nashua, NH (US); Kenneth W. Graham, Nashua, NH (US)

(21) Appl. No.: 15/646,490

(22) Filed: Jul. 11, 2017

(51) Int. Cl. H05K 1/02; H05K 1/18; H01L 23/498; H01L 23/66; H01L 25/18

(52) U.S. Cl. CPC H05K 1/0218; H05K 1/181; H01L 23/49811; H01L 23/49827; H01L 23/49838; H01L 23/49833; H01L 25/105; H01L 25/18; H05K 2201/10159; H01L 2223/6616; H01L 2225/107; H05K 2201/10378; H05K 2201/10545; H01L 23/66

(57) ABSTRACT

In one embodiment, an interposer may include a top surface, a bottom surface, a ground plane disposed between the top surface and bottom surface, an array of top contacts on the top surface, a corresponding array of bottom contacts on the bottom surface, a plurality of through connections between corresponding top and bottom contacts, and a plurality of ground conductors interspersed with the plurality of through connections. The array of top contacts may be configured to interface with a first component above the interposer. The array of bottom contacts may be configured to interface with a second component beneath the interposer. The ground conductors may extend orthogonally through, and be electrically connected to, the ground plane.

### BACKGROUND

The present disclosure relates generally to interposers. In particular, interposers configured to mitigate crosstalk between closely-spaced electrical signal paths are described.

To understand and/or diagnose the operation of a specific component in a circuit it is often necessary to characterize individual signals of the device while it is connected to other functional components. Where the signals are carried by connections which are not readily accessible, such as ball grid arrays, it can be very difficult to find an exposed trace or lead to probe with test equipment. Interposers are used to provide access to a signal from outside the footprint of the component. Often the signal pathways (e.g., vias) running vertically through the interposers are very close together. The close proximity of the vertical pathways can lead to unwanted “crosstalk” between the electrical signals of adjacent pathways, thereby altering the signals.

Thus, there exists a need for interposers that improve upon and advance the design of known interposers. Examples of new and useful interposers relevant to the needs existing in the field are discussed below.

### SUMMARY

In one embodiment, an interposer may comprise a top surface, a bottom surface, a ground plane disposed between the top surface and bottom surface, an array of top contacts on the top surface, a corresponding array of bottom contacts on the bottom surface, a plurality of through connections between corresponding top and bottom contacts, and a plurality of ground conductors interspersed with the plurality of through connections. The array of top contacts may be configured to interface with a first component above the interposer. The array of bottom contacts may be configured to interface with a second component beneath the interposer. The ground conductors may extend orthogonally through, and be electrically connected to, the ground plane.

In one embodiment, the plurality of through connections may be arranged in rows of through connections. Furthermore the plurality of ground conductors may be arranged in rows. The rows of ground conductors are disposed between the rows of through connections. In one embodiment, the first row of through connections may be flanked on both sides by rows of ground conductors.

In one embodiment, the plurality of through connections consists of a first number of individual through connections, the plurality of ground conductors consists of a second number of individual ground conductors, and a ratio of the first number to the second number is in the range of 1:5 to 2:1.

In one embodiment, the plurality of ground conductors is arranged in an equidistant rectangular grid composed of grid elements, wherein a first grid element comprises four ground conductors arranged in a square, and wherein a first through connection is located in a center of the square. In some embodiments, the ground conductors may comprise rod-shaped metal bodies.

In some embodiments, the component connected beneath the interposer may be a System On a Chip (SOC) in a Package On Package (POP) configuration. In other embodiments, interposer the component beneath the interposer may be a printed circuit board (PCB). In some embodiments, the interposer is a first interposer, and the component beneath the first interposer is a second interposer.

An ideal interposer does not change the character of the signal in bringing it outside the component footprint. The interposers described below may mitigate the crosstalk between neighboring vertical signal pathways via vertical (Z-axis) ground conductors. This Z-axis guardbanding results in significantly improved signal characterization.

### BRIEF DESCRIPTION OF THE DRAWINGS

FIG. 1 is a perspective view of a first example of an interposer including Z-axis guardbanding.

FIG. 2 is a side view of a first example of a circuit board, including a memory component on top of a System On a Chip (SOC) in a Package On Package (PoP) configuration.

FIG. 3 is a side view of the circuit board of FIG. 2 with an interposer having Z-axis guardbanding installed between the SOC and the memory component.

FIG. 4 is a side view of a second example of a circuit board, including a memory component installed on the circuit board.

FIG. 5 is a side view of the circuit board of FIG. 4 with two interposers, both having Z-axis guardbanding, installed between the circuit board and the memory component.

### DETAILED DESCRIPTION

The disclosed interposers will become better understood through review of the following detailed description in conjunction with the figures. The detailed description and figures provide merely examples of the various inventions described herein. Those skilled in the art will understand that the disclosed examples may be varied, modified, and altered without departing from the scope of the inventions described herein. Many variations are contemplated for different applications and design considerations; however, for the sake of brevity, each and every contemplated variation is not individually described in the following detailed description.

Throughout the following detailed description, examples of various interposers are provided. Related features in the examples may be identical, similar, or dissimilar in different examples. For the sake of brevity, related features will not be redundantly explained in each example. Instead, the use of related feature names will cue the reader that the feature with a related feature name may be similar to the related feature in an example explained previously. Features specific to a given example will be described in that particular example. The reader should understand that a given feature need not be the same or similar to the specific portrayal of a related feature in any given figure or example.

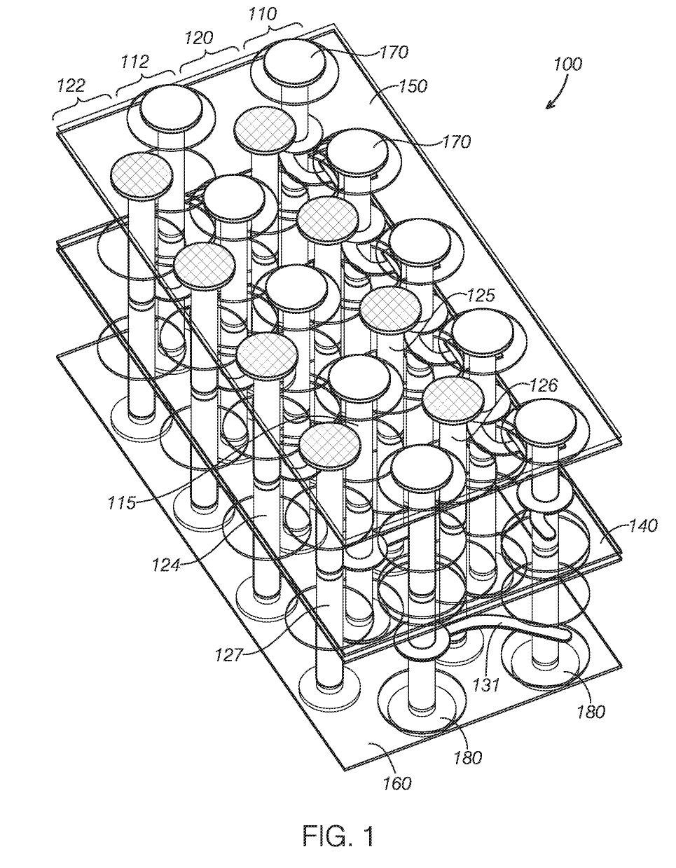

With reference to FIGS. 1-5, one embodiment of an interposer, interposer 100, will now be described. Interposer 100 functions to route electrical signals between an array of top contacts and a corresponding array of bottom contacts. The reader will appreciate from the figures and description below that interposer 100 addresses shortcomings of conventional interposers.

FIG. 1 shows an interposer 100 having a top surface 150, a bottom surface 160, a ground plane 140 disposed between the top surface 150 and the bottom surface 160, a plurality of through connections arranged in rows 110, 112, and a plurality of ground conductors arranged in rows 120, 122. Top surface 150 includes an array of top contacts 170 configured to interface with a first component above interposer 100. Bottom surface 160 includes a corresponding array of bottom contacts 180 configured to interface with a second component beneath the interposer 100.

As used herein, an “interposer” is a component configured to route electrical signals between an array of top contacts and a corresponding array of bottom contacts. In one embodiment, one or more interposers may be inserted between a component of a circuit board (such as a memory chip or a processor, among others) and the circuit board itself. For example, a memory chip may be removed from the circuit board, one or more interposers may be connected to the circuit board in place of the memory chip, and the memory chip may be connected on top of the one or more interposers. In one embodiment, an interposer may include one or more signal probe points configured to allow measurement of the electrical signals passing between one or more corresponding sets of top and bottom contacts.

The top and bottom arrays of pads or contacts may be formed in an insulating substrate. The rows of through connections 110, 112 connect the top contacts 170 to the bottom contacts 180. Thus, each interposer pad may be electrically connected to a corresponding pad of the opposite side via the through connections. The array can include any number of contacts. The pad size and array configuration may vary and the pads can be vias, electroplated contacts with traces or another configuration.

The arrays of contacts may include a plurality of contacts in a repeating pattern. The repeating pattern may be repeating rows with contacts at regular intervals. A separate set of contacts with the same repeating pattern may occur on the opposite side of interposer 100.

Corresponding top and bottom contacts may include a plated pad, a solder ball or the exposed top of a via. Alternatively, corresponding top and bottom contacts may comprise the ends of a spring contact or other conductor passing through the board.

Some or all of the contacts have an electrical connection between corresponding top and bottom contacts such as top and bottom pads with a trace between them or a via. A via for the purposes of this disclosure is a conductor that passes vertically through a circuit board opening to top and bottom surfaces of the board. The via may be a plated through hole, a trace or a filled hole that electrically connects a contact to a corresponding contact.

Thus, the repeating pattern of the top and bottom contact arrays may correspond to a repeating pattern of electrical through connections, for example, rows 110, 112 as depicted in FIG. 1. The vertical through connections may be spaced closely together, as required by the layout of the top and bottom contact arrays. Because of this close spacing as well as the high speeds of the signals passing through the through connections, conventional interposers in this application may suffer from crosstalk between the vertical through connections.

The inventors have found, however, that the plurality of vertical ground conductors dispersed throughout interposer 100 may significantly reduce crosstalk between the electrical through connections. The vertical ground conductors may be electrically connected to each other and to a ground path via ground plane 140.

One particularly useful distribution of ground conductors is shown in FIG. 1. As can be seen, a row of through connections, e.g., row 112, may be flanked on both sides by rows of ground conductors 120, 122. The rows of ground conductors 120, 122 may be disposed between the rows of through connections 110, 112 in a staggered configuration such that at least some of the through connections are surrounded on all four sides by ground conductors. For example, through connection 115 is surrounded on all four sides by ground conductors 124, 125, 126, 127. Thus, in some embodiments, the plurality of ground conductors may be arranged in an equidistant rectangular grid composed of grid elements (e.g., squares formed via four ground conductors such as ground conductors 124, 125, 126, 127). In some embodiments, individual through connections (e.g., through connect 115) may be located in the center of the grid element. In other embodiments, the ground conductors may be dispersed throughout interposer 100 in other patterns.

In one embodiment, interposer 100 may be imagined to have a point of origin at one corner and each contact on the bottom of the board has an orthogonal xy coordinate, the top of the board having corresponding contacts with the same xy coordinate. As described above, the ground conductors may extend orthogonally through ground plane 140. Thus, the ground conductors may extend in the z-axis relative to the xy plane defined by the array of contacts. The ground conductors may serve as z-axis guardbanding for the through connections in order to mitigate crosstalk between the through connections.

As shown in FIG. 1, interposer 100 may comprise a similar number of through connections and ground conductors. In one embodiment, the ratio of through connections to ground conductors may be in the rage of 1:5 to 2:1. In one embodiment, the ratio of through connections to ground conductors may be in the rage of 1:4 to 1:1 In one embodiment, the ratio of through connections to ground conductors may be approximately 1:1.

As shown, the ground conductors may take the form of vertically elongate shaped metal bodies. In one embodiment, they may be rod-shaped or cylindrical. In some embodiments, the ground conductors may be formed in similar manner to the through connections.

As shown in FIG. 1, the through connections may have horizontal signal traces, for example trace 131, to bring the signal to the edge of the interposer 100 to be tested. Methods of producing such horizontal traces are well known.

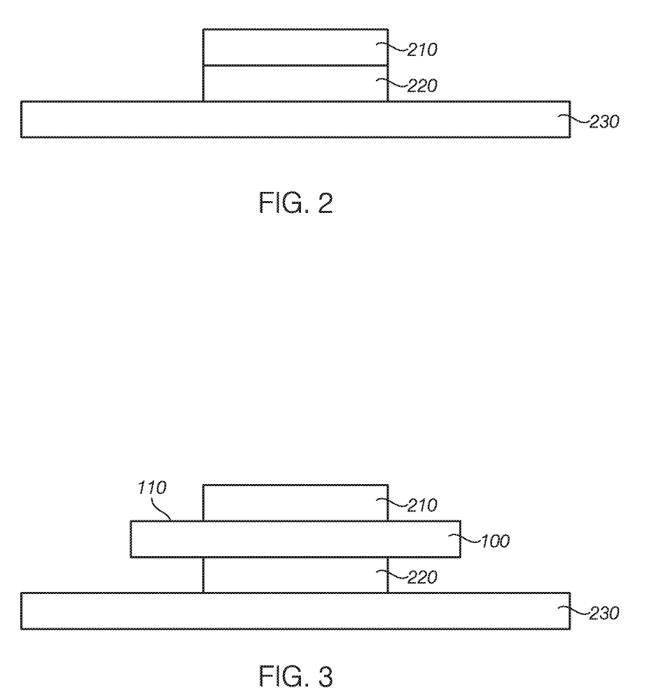

Turning now to FIG. 2, one embodiment of a circuit board, circuit board 230 is shown. Circuit board 230 including a memory component 210 on top of a System On a Chip (SOC) 220 in a Package On Package (PoP) configuration. As shown in FIG. 3, interposer 100 may be inserted between memory component 210 and SOC 220.

Interposer 100 may have a larger footprint than both the memory component 210 and the SOC 220 to allow for probe points to be exposed for testing. Interposer 100 may have surface contacts or pads configured to match those of the interface between the memory component 210 and the SOC 220. In the illustrated configuration, SOC 220 provides clearance between the board 230 and the sides of the interposer that extend beyond the footprint of SOC 220.

When interposer 100 is stacked between memory component 210 and the SOC 220, signals can pass between memory component 210 and the SOC 220 in a through connection between corresponding contacts. Contacts of the arrays may include solder and system assembly may include reflow of the solder. The arrays may be a ball grid array configuration with solder on each contact. Ball grid array configurations and connection methods are well known to those skilled in the art.

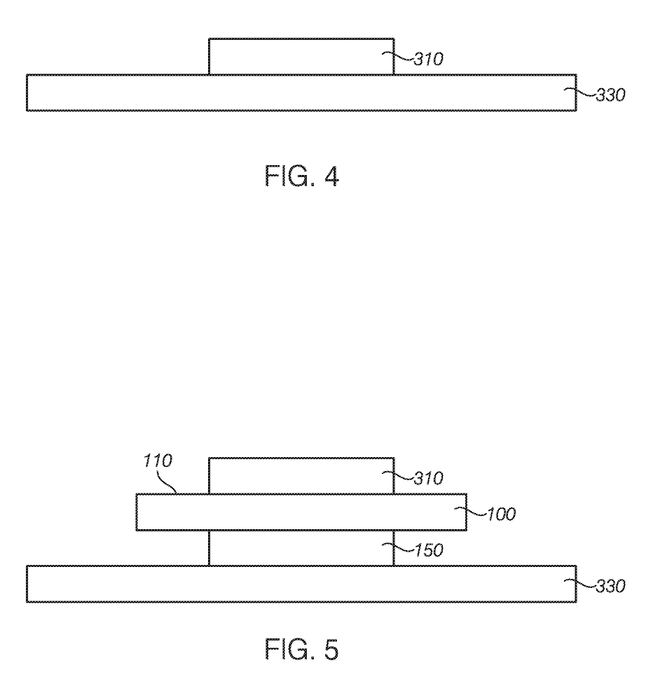

Turning now to FIG. 4, a second embodiment of a circuit board, circuit board 330 is shown. Circuit board 330 includes a memory component 310 installed directly onto the circuit board. As described above, interposer 100 may have a larger footprint than the components being tested, thus, in the configuration shown in FIG. 4, two interposers may be stacked between circuit board 330 and the memory component 310. Specifically, interposer 150 may be stacked below interposer 100.

Interposer 150 may have the same or similar footprint to memory component 310. Interposer 150 function to provide clearance for the edges of interposer 100 that extend beyond the footprint of memory component 310.

FIGS. 3 and 5 show illustrative examples of the use of interposer 100. In other embodiments, interposer 100 may be used to test other components on a circuit board, such as processors, CPUs, or any other component connected to the circuit board via an array of contacts. Circuit board 230 may include additional components (not pictured) assembled to the board such as discrete passive components, memory and processors.

The substrate of interposer 100 may be a multilayer substrate with traces on inner layers to create circuits. Electrical components such as resistors, capacitors and inductors may be configured on inner layers as well. Electrical components may be included on the substrate surface. The substrate of interposer 10 may be FR4, ceramic or other insulating material. Contacts and electrical connections may be copper, lead, silver aluminum or other conductor.

The physical configurations shown are examples for the purpose of explanation as well. Interposer 100 may have any number of pads and edge contacts and may be in a configuration different than that shown here. Interposer 100 may be configured to be used with interconnection systems other than ball grid arrays.

The disclosure above encompasses multiple distinct inventions with independent utility. While each of these inventions has been disclosed in a particular form, the specific embodiments disclosed and illustrated above are not to be considered in a limiting sense as numerous variations are possible. The subject matter of the inventions includes all novel and non-obvious combinations and subcombinations of the various elements, features, functions and/or properties disclosed above and inherent to those skilled in the art pertaining to such inventions. Where the disclosure or subsequently filed claims recite “a” element, “a first” element, or any such equivalent term, the disclosure or claims should be understood to incorporate one or more such elements, neither requiring nor excluding two or more such elements.

Applicant(s) reserves the right to submit claims directed to combinations and subcombinations of the disclosed inventions that are believed to be novel and non-obvious. Inventions embodied in other combinations and subcombinations of features, functions, elements and/or properties may be claimed through amendment of those claims or presentation of new claims in the present application or in a related application. Such amended or new claims, whether they are directed to the same invention or a different invention and whether they are different, broader, narrower or equal in scope to the original claims, are to be considered within the subject matter of the inventions described herein.

1. An interposer comprising:
a top surface;
a bottom surface;
a ground plane disposed between the top surface and bottom surface;
an array of top contacts on the top surface configured to interface with a first component above the interposer,
a corresponding array of bottom contacts on the bottom surface configured to interface with a second component beneath the interposer,
a plurality of through connections between corresponding top and bottom contacts;
a plurality of signal traces, each respective signal trace configured to allow an electrical signal traveling through a respective through connection to be tested at a location near the edge of the interposer; and
a plurality of ground conductors interspersed with the plurality of through connections, wherein the ground conductors extend orthogonally through, and are electrically connected to, the ground plane.

2. The interposer of claim 1, wherein the plurality of through connections is arranged in rows of through connections, wherein the plurality of ground conductors is arranged in rows, and wherein the rows of ground conductors are disposed between the rows of through connections.

3. The interposer of claim 2, wherein a first row of through connections is flanked on both sides by rows of ground conductors.

4. The interposer of claim 1, wherein the plurality of through connections consists of a first number of individual through connections, wherein the plurality of ground conductors consists of a second number of individual ground conductors, and wherein a ratio of the first number to the second number is in the range of 1:5 to 2:1.

5. The interposer of claim 1, wherein the plurality of ground conductors is arranged in an equidistant rectangular grid composed of grid elements, wherein a first grid element comprises four ground conductors arranged in a square, and wherein a first through connection is located in a center of the square.

6. The interposer of claim 1, wherein the ground conductors comprise rod-shaped metal bodies.

7. The interposer of claim 1, wherein the component beneath the interposer is a System On a Chip (SOC) in a Package On Package (PoP) configuration.

8. The interposer of claim 1, wherein the component beneath the interposer is a printed circuit board (PCB).

9. The interposer of claim 1, wherein the interposer is a first interposer, and wherein the component beneath the first interposer is a second interposer.

10. An interposer comprising:
a top surface;
a bottom surface;
a ground plane disposed between the top surface and bottom surface;
an array of top contacts on the top surface configured to interface with a first component above the interposer;
a corresponding array of bottom contacts on the bottom surface configured to interface with a second component beneath the interposer;
a plurality of through connections between corresponding top and bottom contacts;
a plurality of signal traces, each respective signal trace configured to allow an electrical signal traveling through a respective through connection to be tested at a location near the edge of the interposer;
a plurality of ground conductors interspersed with the plurality of through connections, wherein the ground conductors extend orthogonally through, and are electrically connected to, the ground plane;
wherein the plurality of ground conductors is arranged in an equidistant rectangular grid composed of grid elements, wherein a first grid element comprises four ground conductors arranged in a square, and wherein a first through connection is located in a center of the square.

11. The interposer of claim 10, wherein the plurality of through connections is arranged in rows of through connections, wherein the plurality of ground conductors is arranged in rows, and wherein the rows of ground conductors are disposed between the rows of through connections.

12. The interposer of claim 11, wherein a first row of through connections is flanked on both sides by rows of ground conductors.

13. The interposer of claim 10, wherein the plurality of through connections consists of a first number of individual through connections, wherein the plurality of ground conductors consists of a second number of individual ground conductors, and wherein a ratio of the first number to the second number is in the range of 1:5 to 2:1.

14. The interposer of claim 10, wherein the ground conductors comprise rod-shaped metal bodies.

15. The interposer of claim 10, wherein the component beneath the interposer is a System On a Chip (SOC) in a Package On Package (PoP) configuration.

16. The interposer of claim 10, wherein the component beneath the interposer is a printed circuit board (PCB).

17. The interposer of claim 10, wherein the interposer is a first interposer, and wherein the component beneath the first interposer is a second interposer.

18. An interposer comprising:
a top surface;
a bottom surface;
a ground plane disposed between the top surface and bottom surface;
an array of top contacts on the top surface configured to interface with a first component above the interposer,
a corresponding array of bottom contacts on the bottom surface configured to interface with a second component beneath the interposer,
a plurality of through connections between corresponding top and bottom contacts;
a plurality of signal traces, each respective signal trace configured to allow an electrical signal traveling through a respective through connection to be tested at a location near the edge of the interposer;
a plurality of ground conductors interspersed with the plurality of through connections, wherein the ground conductors extend orthogonally through, and are electrically connected to, the ground plane;
wherein the plurality of ground conductors is arranged in an equidistant rectangular grid composed of grid elements, wherein a first grid element comprises four ground conductors arranged in a square, and wherein a first through connection is located in a center of the square; and
wherein the plurality of through connections consists of a first number of individual through connections, wherein the plurality of ground conductors consists of a second number of individual ground conductors, and wherein a ratio of the first number to the second number is in the range of 1:5 to 2:1.

19. The interposer of claim 18, wherein the ground conductors comprise rod-shaped metal bodies.

20. The interposer of claim 18, wherein the component beneath the interposer is a System On a Chip (SOC) in a Package On Package (PoP) configuration.
